(19) United States
(12) Patent Application Publication
(10) Pub. No.: US 2014/0132303 A1
(43) Pub. Date: May 15, 2014

(54) APPARATUS AND METHOD FOR SENSING TRANSISTOR MISMATCH

(71) Applicant: LSI CORPORATION, Milpitas, CA (US)

(72) Inventors: Scott A. Segan, Allentown, PA (US); Richard P. Martin, Macungie, PA (US); Richard Muscavage, Gilbertsville, PA (US); James D. Chlipala, Emmaus, PA (US); Michael S. Buonpane, Easton, PA (US)

(73) Assignee: LSI Corporation, Milpitas, CA (US)

(21) Appl. No.: 13/673,680

(22) Filed: Nov. 9, 2012

(51) Int. Cl. G01R 31/26

(52) U.S. Cl. CPC G01R 31/2621
USPC 324/762.01

(57) ABSTRACT

An integrated circuit implements a transistor mismatch sensor comprising first and second inverter chains coupled to a register. The register comprises a plurality of flip-flops having clock inputs driven by an output of the first inverter chain and data inputs driven by an output of the second inverter chain. Data outputs of the flip-flops of the register are indicative of an amount of mismatch between transistors of different conductivity types in the first and second inverter chains. For example, the register may comprise a thermometer encoded register providing a digital output signal having a first value indicative of an approximate match in speed, drive strength or other characteristics between the transistors of the first and second conductivity types, with values above and below the first value being indicative of respective first and second different types of relative mismatch in speed, drive strength or other characteristics.

### BACKGROUND

Integrated circuits are often designed to incorporate various types of test circuitry. For example, it is well known to configure an integrated circuit to include scan test circuitry that facilitates testing for various internal fault conditions using applied test patterns. These internal fault conditions in many cases can be attributable at least in part to process-dependent differences in speed, drive strength or other characteristics between transistors of different conductivity types, such as n-type metal-oxide-semiconductor (NMOS) transistors and p-type metal-oxide-semiconductor (PMOS) transistors.

It is therefore often desirable to implement functionality for sensing transistor mismatch in an integrated circuit. For example, in conjunction with scan testing or other types of testing, transistor mismatch measurements may be useful in determining particular test patterns to apply, or in interpreting or otherwise processing test results. Additionally or alternatively, such measurements may be used in characterizing the ability of an integrated circuit to meet performance requirements under various environmental conditions, or in adjusting manufacturing processes to increase integrated circuit yield.

Unfortunately, conventional techniques generally fail to provide a sufficient level of accuracy and efficiency in the sensing of transistor mismatch. For example, such techniques may require the use of analog circuitry that is difficult to incorporate into an integrated circuit, or may consume excessive amounts of power within the integrated circuit. Also, the measurements generated by conventional techniques are typically not independent of voltage, temperature or clock frequency.

### SUMMARY

Embodiments of the invention provide improved transistor mismatch sensors that may be implemented within an integrated circuit and controlled, for example, by an external or internal tester.

In one embodiment, an integrated circuit implements a transistor mismatch sensor comprising first and second inverter chains coupled to a register. The register comprises a plurality of flip-flops having clock inputs driven by an output of the first inverter chain and data inputs driven by an output of the second inverter chain. Data outputs of the flip-flops of the register are indicative of an amount of mismatch between transistors of different conductivity types in the first and second inverter chains.

By way of example, the register may illustratively comprise a thermometer encoded register providing a digital output signal having a first value indicative of an approximate match in speed, drive strength or other characteristics between the transistors of the first and second conductivity types, with values above and below the first value being indicative of respective first and second different types of relative mismatch in speed, drive strength or other characteristics between the transistors of the first and second conductivity types.

The first and second inverter chains may each comprise an initial inverter and at least one additional inverter arranged in series with the initial inverter, with an output of the initial inverter being heavily loaded so as to exaggerate transition timing differences between the transistors of the different conductivity types in the corresponding inverter chains. For example, the output of the initial inverter in a given one of the first and second inverter chains may be heavily loaded by coupling that output to inputs of respective additional inverters each having a drive strength that is substantially larger than a drive strength of the initial inverter. As a more particular example, the drive strength of a given one of the additional inverters may be at least about 16 times the drive strength of the initial inverter.

The transition timing differences referred to above may illustratively be reflected in a difference between a pulse width from a rising edge to a falling edge in one of the first and second inverter chains and a pulse width from a falling edge to a rising edge in the other of the first and second inverter chains. In such an arrangement, this type of difference in transition timing between the first and second inverter chains is measured by the register to determine an amount of transistor mismatch.

One or more of the illustrative embodiments provide significant improvements relative to conventional practice. For example, a given such embodiment is implemented in the form of an all-digital transistor mismatch sensor in which measurements are substantially independent of voltage and temperature. Also, due to the self-timed configuration of the sensor, the measurements are substantially independent of clock frequency. Moreover, the transistor mismatch sensor is implemented so as to consume dynamic power only when making a measurement, and therefore without unduly increasing the power consumption of the corresponding integrated circuit.

### BRIEF DESCRIPTION OF THE DRAWINGS

FIG. 1 is a block diagram of an integrated circuit testing system comprising an integrated circuit that incorporates a transistor mismatch sensor in an illustrative embodiment.

FIG. 2 shows a more detailed view of one embodiment of a tester of the FIG. 1 system.

FIG. 3 shows a more detailed view of one embodiment of the transistor mismatch sensor of the FIG. 1 system.

FIG. 4 is a timing diagram illustrating the operation of the FIG. 3 transistor mismatch sensor.

FIGS. 5A through 5D are timing diagrams illustrating signals of the FIG. 3 transistor mismatch sensor for respective different types of relative mismatch between NMOS and PMOS transistors.

### DETAILED DESCRIPTION

Embodiments of the invention will be illustrated herein in conjunction with exemplary testing systems and associated integrated circuits comprising transistor mismatch sensors configured to determine mismatches in speed, drive strength or other characteristics between NMOS and PMOS transistors of the integrated circuits. It should be understood, however, that embodiments of the invention are more generally applicable to any testing system or associated integrated circuit in which it is desirable to provide sensing of transistor mismatch. Additional embodiments may be implemented using components other than those specifically shown and described in conjunction with the illustrative embodiments.

FIG. 1 shows an embodiment of the invention in which a testing system 100 comprises an integrated circuit 102 coupled to a tester 104. The integrated circuit 102 comprises a transistor mismatch sensor 110 and additional circuitry 112. The tester 104 in the present embodiment is an external tester relative to the integrated circuit 102. In other embodiments, at least a portion of the tester 104 may be incorporated into the integrated circuit 102. For example, substantially the entire tester 104 may be incorporated into the integrated circuit 102, as in a built-in self-test (BIST) arrangement.

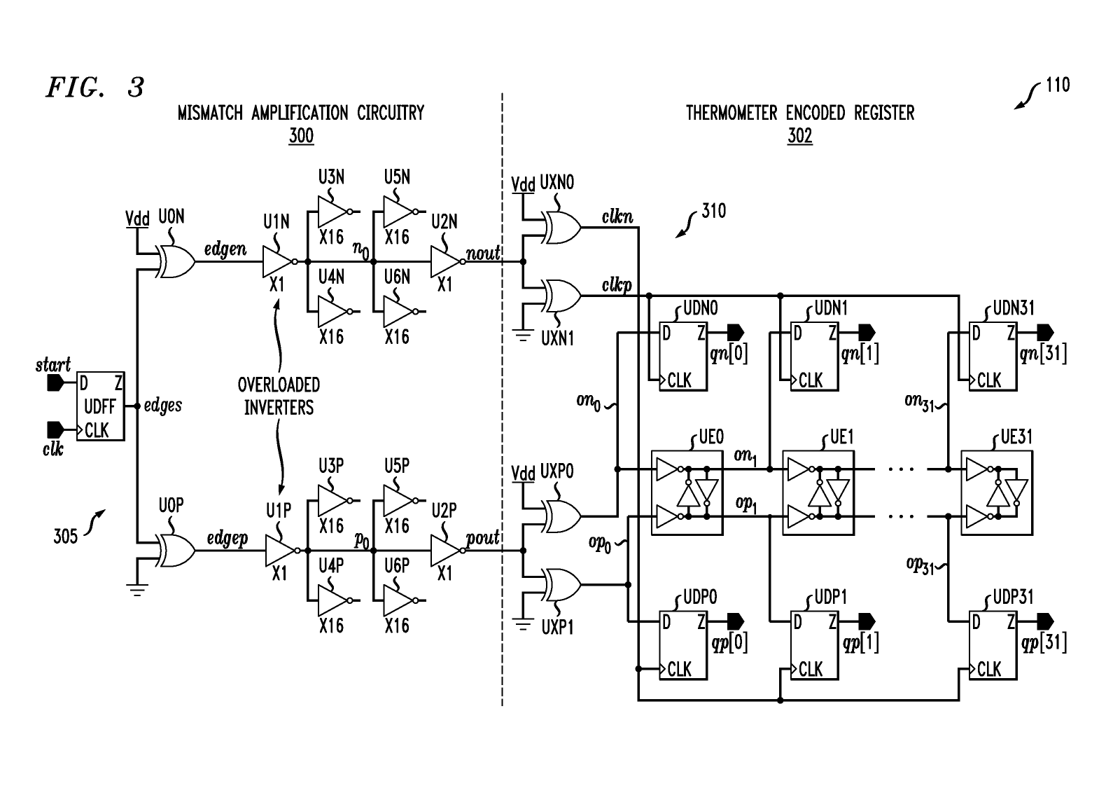

As will be described in greater detail below in conjunction with FIGS. 3 through 5, the transistor mismatch sensor 110 of integrated circuit 102 in one embodiment comprises first and second inverter chains, and a register comprising a plurality of flip-flops having clock inputs driven by an output of the first inverter chain and data inputs driven by an output of the second inverter chain. The data outputs of the flip-flops of the register are indicative of an amount of mismatch between transistors of different conductivity types in the first and second inverter chains, such as mismatch between NMOS and PMOS transistors in the first and second inverter chains. The register may be implemented, for example, as an output register comprising multiple banks of flip-flops, or in a wide variety of other configurations.

The term “mismatch” as used herein is intended to be broadly construed so as to encompass, for example, differences in speed, drive strength or other transistor characteristics. Such differences may be attributable to process variations, temperature variations or other factors, in any combination.

Also, terms such as “driven” and “driving” are intended to encompass both direct and indirect driving arrangements. Thus, for example, in the case of an input driven by an output of an inverter chain, one or more circuitry elements may be arranged between the output and the input.

The additional circuitry 112 may comprise, for example, multiple integrated circuit cores, such as respective read channel and additional cores of a system-on-chip (SOC) integrated circuit in a hard disk drive (HDD) controller application, designed for reading and writing data from one or more magnetic storage disks of an HDD. In other embodiments, the additional circuitry 112 may comprise other types of functional logic circuitry, in any combination, and the term “additional circuitry” is intended to be broadly construed so as to cover any such arrangements of logic circuitry.

The particular configuration of testing system 100 as shown in FIG. 1 is exemplary only, and the testing system 100 in other embodiments may include other elements in addition to or in place of those specifically shown, including one or more elements of a type commonly found in a conventional implementation of such a system. For example, various elements of the integrated circuit 102 or tester 104 may be implemented, by way of illustration only and without limitation, utilizing a microprocessor, central processing unit (CPU), digital signal processor (DSP), application-specific integrated circuit (ASIC), field-programmable gate array (FPGA), or other type of data processing device, as well as portions or combinations of these and other devices.

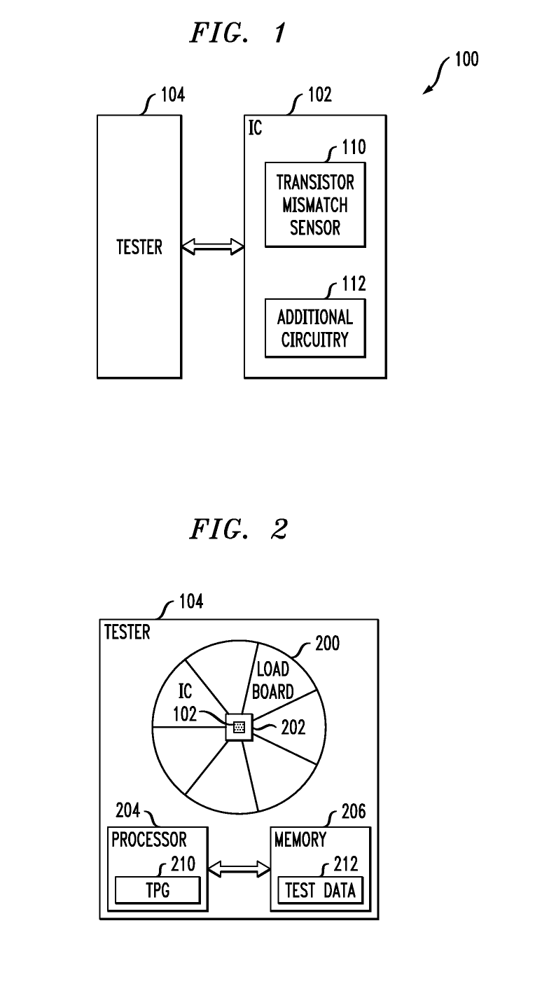

Referring now to FIG. 2, one possible implementation of tester 104 is shown in greater detail. In this embodiment, tester 104 comprises a load board 200. The integrated circuit 102 is to be subject to testing for transistor mismatch using transistor mismatch sensor 110 and is installed in a central portion 202 of the load board 200. The tester 104 also comprises processor and memory elements 204 and 206. In the present embodiment, processor 204 is shown as implementing a test pattern generator 210, also denoted in the figure as a TPG. Associated test data 212 is stored in memory 206. The test data may include, for example, transistor mismatch test results obtained by utilizing the transistor mismatch sensor 110 under the control of one or more test signals generated by the tester 104.

Portions of the tester 104 may be implemented at least in part in the form of software stored in memory 206 and executed by processor 204. For example, the memory 206 may store program code that is executed by the processor 204 to implement particular testing operations that utilize the transistor mismatch sensor 110 of integrated circuit 102. The memory 206 is an example of what is more generally referred to herein as a computer-readable medium or other type of computer program product having computer program code embodied therein, and may comprise, for example, electronic memory such as RAM or ROM, magnetic memory, optical memory, or other types of storage devices in any combination. The processor 204 may comprise a microprocessor, CPU, ASIC, FPGA or other type of processing device, as well as portions or combinations of such devices. Similar processor and memory elements may be used to implement at least a portion of the transistor mismatch sensor 110, as well as other portions of the integrated circuit 102.

It should be noted that the FIG. 2 embodiment of tester 104 should not be construed as limiting in any way. In other embodiments, various conventional testing system arrangements can be modified in a straightforward manner to support the transistor mismatch sensing functionality disclosed herein. Accordingly, numerous alternative testers may be used to perform transistor mismatch testing of an integrated circuit as disclosed herein. Also, as indicated previously, in other embodiments one or more portions of an external tester may be incorporated into the integrated circuit itself, as in BIST arrangement.

FIG. 3 shows an embodiment of the transistor mismatch sensor 110. In this embodiment, the transistor mismatch sensor 110 comprises mismatch amplification circuitry 300 coupled to a thermometer encoded register 302. The mismatch amplification circuitry comprises first and second inverter chains. The thermometer encoded register 302 is an example of what is more generally referred to herein as a “register,” and other types of registers may be used in other embodiments. Such a register comprises a plurality of flip-flops having clock inputs driven by an output of the first inverter chain and data inputs driven by an output of the second inverter chain, with data outputs of the flip-flops of the register being indicative of an amount of mismatch between transistors of different conductivity types in the first and second inverter chains. The term “register” as used herein is intended to be broadly construed, and may comprise, for example, one or more banks of flip-flops.

The first inverter chain of the mismatch amplification circuitry 300 comprises inverters U1N and U2N and the second inverter chain comprises inverters U1P and U2P. The inverters U1N and U1P are the initial inverters of the respective inverter chains, and although each inverter chain in this embodiment comprises a series arrangement of two inverters, other embodiments may use series arrangements of more than two inverters to form the first and second inverter chains.

It should be noted that the circuits driving the inputs of the respective first and second inverter chains should generally have the same or similar drive strengths.

The output of the initial inverter in each of the first and second inverter chains is overloaded or otherwise heavily loaded in the present embodiment in order to exaggerate transition timing differences between transistors of different conductivity types in the corresponding inverter chain. The transition timing differences may be reflected in a difference between a pulse width from a rising edge to a falling edge in one of the first and second inverter chains and a pulse width from a falling edge to a rising edge in the other of the first and second inverter chains.

The output of initial inverter U1N in the first inverter chain is heavily loaded by coupling that output to inputs of four additional inverters U3N, U4N, U5N and U6N at node n₀, where each of the additional inverters has a drive strength X16 that is approximately at least about 16 times the drive strength X1 of the initial inverter. Similarly, the output of initial inverter U1P in the second inverter chain is heavily loaded by coupling that output to inputs of four additional inverters U3P, U4P, U5P and U6P at node p₀, where one again each of the additional inverters has a drive strength X16 that is approximately at least about 16 times the drive strength X1 of the initial inverter. The outputs of the first and second inverter chains are denoted nout and pout, respectively.

The mismatch amplification circuitry 300 further comprises an input circuit 305 configured to generate complementary input signals edgen and edgep for application to respective inputs of the first and second inverter chains. The complementary input signals in the present embodiment have substantially aligned transition times, such that a rising edge of one complementary input signal occurs at substantially the same time as a falling edge of the other complementary input signal, and vice versa. These transition times are substantially aligned regardless of any mismatch between NMOS and PMOS transistors in the input circuit 305.

The input circuit 305 in the present embodiment comprises an input flip-flop UDFF having a data input D driven by a start signal, a clock input driven by a clock signal clk, and a data output Z providing a signal denoted edges. The input circuit 305 further comprises first and second two-input exclusive-or (XOR) gates U0N and U0P each having an input coupled to the data output of the input flip-flop UDFF. The first XOR gate U0N has its other input coupled to an upper supply voltage, illustratively Vdd, and the second XOR gate U0P has its other input coupled to a lower supply voltage, illustratively ground potential. The outputs of the XOR gates U0N and U0P provide the respective complementary input signals edgen and edgep for application to respective inputs of initial inverters U1N and U1P of the first and second inverter chains. As indicated above, inverter chain drive circuits such as XOR gates U0N and U0P in the present embodiment should have similar drive strengths.

The thermometer encoded register 302 comprises input circuitry 310 that includes a first input circuit driven by an output of the first inverter chain and a second input circuit driven by an output of the second inverter chain. The thermometer encoded register 302 further comprises a first bank of flip-flops comprising flip-flops UDN0, UDN1, . . . UDN31 providing respective bits qn[0], qn[1], . . . qn[31] of a first digital output signal, and a second bank of flip-flops comprising flip-flops UDP0, UDP1, . . . UDP31 providing respective bits qp[0], qp[1], . . . qp[31] of a second digital output signal. Although the thermometer encoded register 302 is implemented as a 32-bit register comprising two banks of 32 flip-flops in the present embodiment, registers having a wide variety of other sizes and configurations may be used in other embodiments. Also, although D-type flip-flops are used in this embodiment, other embodiments can utilize other types of flip-flops. The term “flip-flop” as used herein is therefore intended to be broadly construed so as to encompass a wide variety of different types of clocked storage elements.

The first input circuit of the input circuitry 310 comprises a pair of two-input XOR gates UXN0 and UXN1 and generates complementary clock signals clkn and clkp for application to clock inputs of the flip-flops of the respective first and second banks of flip-flops. The second input circuit comprises a pair of two-input XOR gates UXP0 and UXP1 and generates complementary data signals on₀ and op₀ for application to data inputs of the initial flip-flops UDN0 and UDP0 of the respective first and second banks of flip-flops.

Each of the XOR gates UXN0 and UXN1 receives at one of its inputs the output signal nout from inverter U2N of the first inverter chain. The XOR gate UXN0 has its other input coupled to Vdd, and the XOR gate UXN1 has its other input coupled to ground potential. Similarly, each of the XOR gates UXP0 and UXP1 receives at one of its inputs the output signal pout from inverter U2P of the second inverter chain. The XOR gate UXP0 has its other input coupled to Vdd, and the XOR gate UXP1 has its other input coupled to ground potential.

The thermometer encoded register 302 further includes a differential delay line comprising a plurality of differential delay elements UE0, UE1, . . . UE31 arranged in series with one another. Each differential delay element comprises four inverters, including two series inverters that pass delay element inputs to corresponding Outputs, and a pair of cross-coupled weak inverters configured to balance rise and fall times between the two outputs of the differential delay element. This exemplary differential delay element provides a timing resolution of one inverter delay.

The initial one of the differential delay elements UE0 has first and second inputs coupled to respective outputs of the XOR gates UXP0 and UXP1 and receives the respective complementary data signals on₀ and op₀ therefrom.

Each of the differential delay elements other than the final one of the differential delay elements UE31 has first and second outputs that are coupled to respective data inputs of corresponding flip-flops in the first and second banks of flip-flops. Thus, for example, the first differential delay element UE0 has data outputs on₁ and op₁ that are coupled to respective data inputs of flip-flops UDN1 and UDP1 and to respective data inputs of the next differential delay element UE1. Similarly, the second differential delay element UE1 has data outputs on₂ and op₂ that are coupled to respective data inputs of flip-flops UDN2 and UDP2 and to respective data inputs of the next differential delay element UE2, and so on through the differential delay line.

This exemplary arrangement creates a race condition between the clock signal clkp and the data signals on₀, on₁, . . . on₃₁ of the first bank of flip-flops UDN0 through UDN31 that controls the respective bits qn[0], qn[1], . . . qn[31] of the first digital output signal, and a race condition between the clock signal clkn and the data signals op₀, op₁, . . . op₃₁ of the second bank of flip-flops UDP0 through UDP31 that controls the respective bits qp[0], qp[1], . . . qp[31] of the second digital output signal.

As noted above, the digital output signals comprising data outputs of the flip-flops of the first and second banks of flip-flops in the thermometer encoded register 302 are indicative of an amount of mismatch between transistors of different conductivity types in the first and second inverter chains.

The transistors of the first and second conductivity types in the present embodiment may be assumed to comprise respective NMOS and PMOS transistors. A given one of the digital output signals has a first value indicative of an approximate match in speed between the NMOS and PMOS transistors. The digital output signal having a value less than the first value indicates that the NMOS transistors are slower than the PMOS transistors and the digital output signal having a value greater than the first value indicates that the NMOS transistors are faster than the PMOS transistors. Alternatively, the digital output signal having a value less than the first value may indicate that the PMOS transistors are slower than the NMOS transistors and the digital output signal having a value greater than the first value may indicate that the PMOS transistors are faster than the NMOS transistors. The digital output signals may be similarly utilized to indicate differences in drive strength or other characteristics between the NMOS and PMOS transistors.

It should be noted in this regard that the speed of an NMOS or PMOS transistor is closely related to its drive strength. Thus, embodiments described herein with reference to sensing mismatch between NMOS and PMOS transistor speed may be understood to also be indicative of mismatches between NMOS and PMOS drive strength.

In the FIG. 3 embodiment, mismatch between NMOS and PMOS transistors occurs primarily at nodes n₀ and p₀ of the respective first and second inverter chains. Accordingly, the rise and fall times for nodes n₀ and p₀ are substantially larger than for other nodes in the transistor mismatch sensor 110. As indicated above, the nodes n₀ and p₀ are complementary, such that when n₀=1, p₀=0 and vice versa. The inputs to the first delay line element UE0 are also complementary, and the delay line is configured to preserve this complementarity through its entire length.

The outputs qp[31:0] are the Z outputs of rising edge triggered flip-flops UDP[31:0]. The 0→1 transitions at the respective CLK inputs of UDP[31:0] are caused by a corresponding 0→1 transition on n₀, which is caused by the PMOS transistors of inverter U1N. When n₀ experiences a 0→1 transition, p₀ experiences a 1→0 transition, which is caused by the NMOS transistors of inverter U1P. The 1→0 transition on p₀ causes a 0→1 transition on the D input of UDP0 and one of the inputs of UE0. The delay line formed by UE[31:0] “propagates” the transition edges down its length. Accordingly, the PMOS-derived CLK edges cause UDP[31:0] to latch NMOS-derived D inputs.

The outputs qn[31:0] are the Z outputs of rising edge triggered flip-flops UDN[31:0]. The 0→1 transitions at the respective CLK inputs of UDN[31:0] are caused by a corresponding 1→0 transition on n₀, which is caused by the NMOS transistors of inverter U1N. When n₀ experiences a 1→0 transition, p₀ experiences a 0→1 transition, which is caused by the PMOS transistors of inverter U1P. The 0→1 transition on p₀ causes a 0→1 transition on the D input of UDN0 and one of the inputs of UE0. The delay line formed by UE[31:0] “propagates” the transition edges down its length. Accordingly, the NMOS-derived CLK edges cause UDN[31:0] to latch PMOS-derived D inputs.

Under an exemplary targeted nominal condition, which may correspond to substantially no mismatch between the NMOS and PMOS transistors of the inverter chains, the outputs qp[31:0] and qn[31:0] are both at the same targeted nominal value, assumed for this example to be 0x00007FFF, which is in hexadecimal notation.

If the PMOS transistors are faster than the targeted nominal and the NMOS transistors are slower than the targeted nominal, the output qp[31:0] will be below the targeted nominal value and the output qn[31:0] will be above the targeted nominal value. Thus, for example, the output qp[31:0] may be 0x0000007F, and the output qn[31:0] may be 0x007FFFFF. This is because qp[31:0] is generated using PMOS-derived CLK edges to cause UDP[31:0] to latch NMOS-derived D inputs, with the PMOS-derived CLK edges arriving earlier than nominal and the NMOS-derived D inputs arriving later than nominal, and because qn[31:0] is generated using NMOS-derived CLK edges to cause UDN[31:0] to latch PMOS-derived D inputs, with the NMOS-derived CLK edges arriving later than nominal and the PMOS-derived D inputs arriving earlier than nominal.

If the PMOS transistors are slower than the targeted nominal and the NMOS transistors are faster than the targeted nominal, the output qp[31:0] will be above the targeted nominal value and the output qn[31:0] will be below the targeted nominal value. Thus, for example, the output qp[31:0] may be 0x007FFFFF, and the output qn[31:0] may be 0x0000007F. Again, this is because qp[31:0] is generated using PMOS-derived CLK edges to cause UDP[31:0] to latch NMOS-derived D inputs, but now with the PMOS-derived CLK edges arriving later than nominal and the NMOS-derived D inputs arriving earlier than nominal, and because qn[31:0] is generated using NMOS-derived CLK edges to cause UDN[31:0] to latch PMOS-derived D inputs, but now with the NMOS-derived CLK edges arriving earlier than nominal and the PMOS-derived D inputs arriving later than nominal.

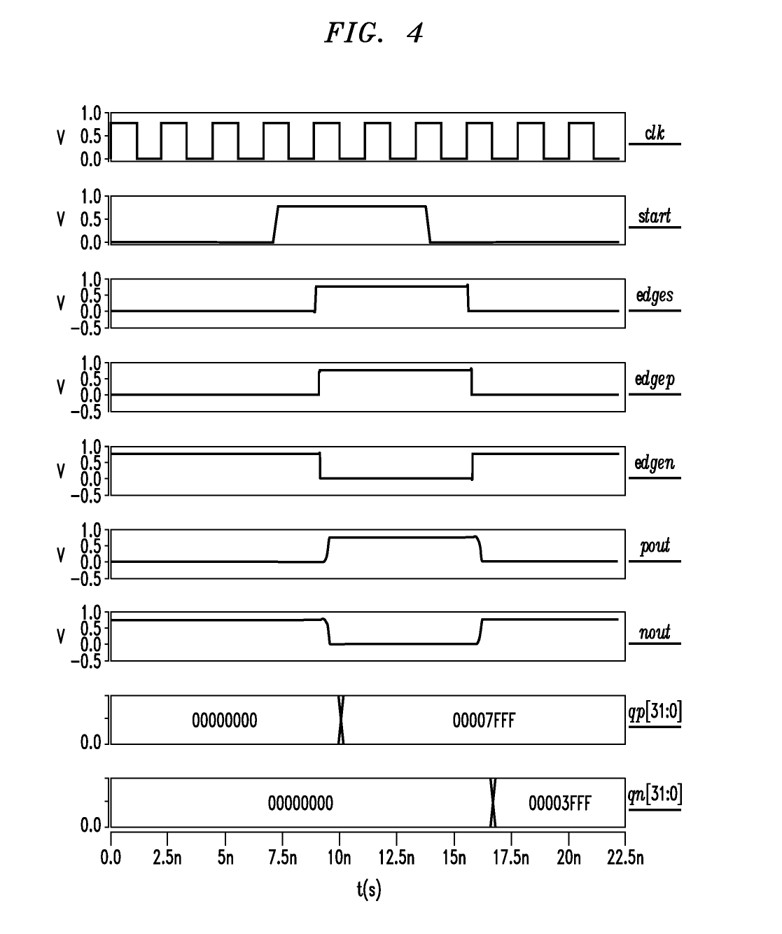

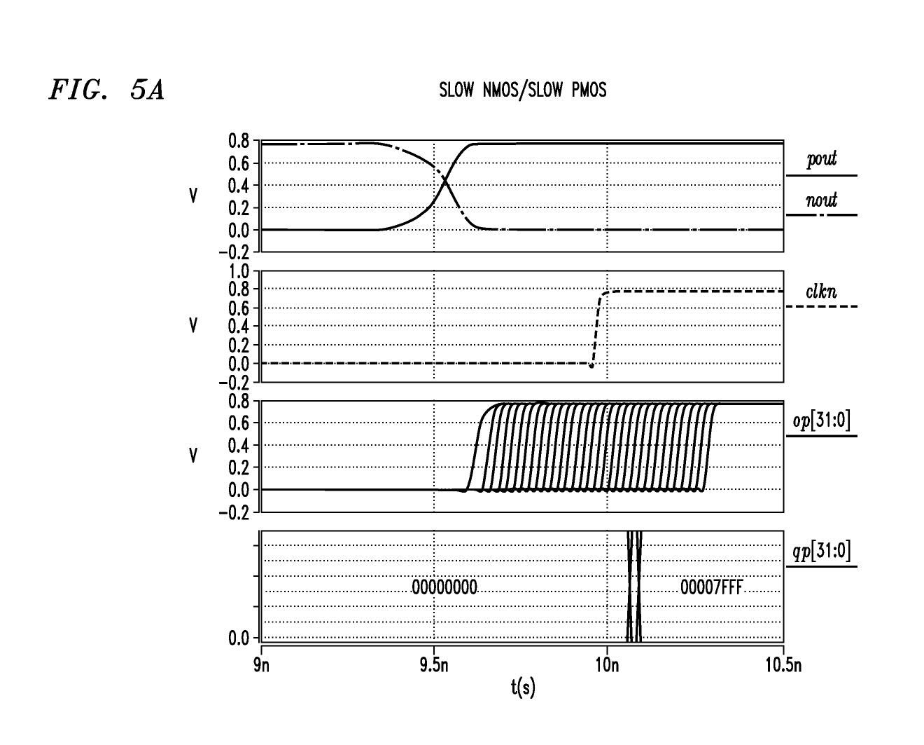

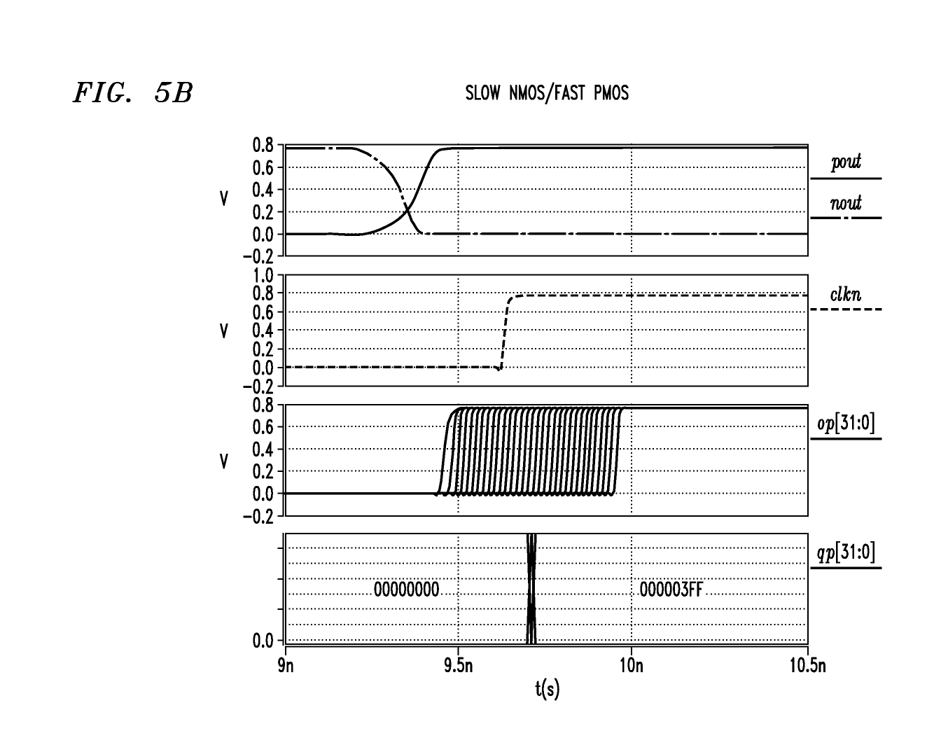

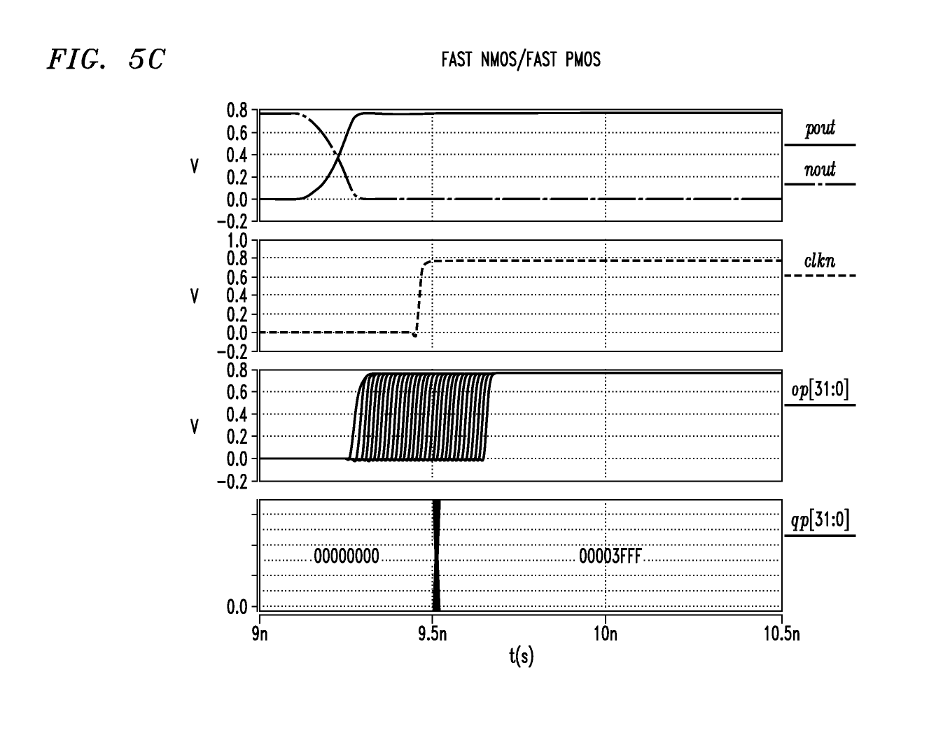

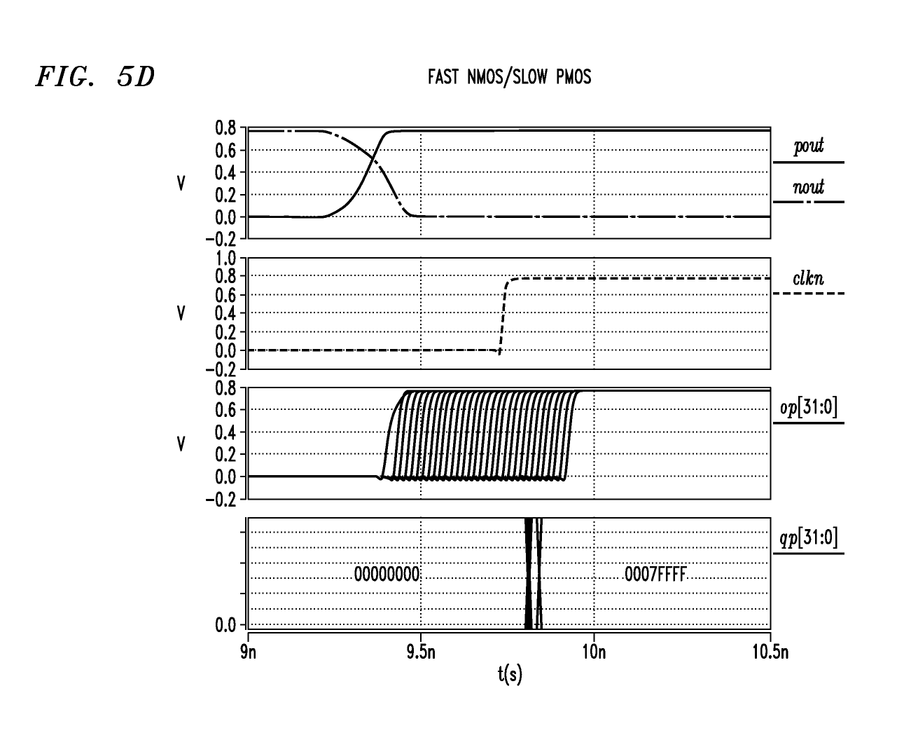

The above-described operation of the transistor mismatch sensor 110 of FIG. 3 will be illustrated in greater detail with reference to the timing diagrams of FIGS. 4 and 5.

The FIG. 4 timing diagram shows the relationships between a number of exemplary signal waveforms in one implementation of the transistor mismatch sensor 110, including signal waveforms for the input clock clk, the start signal, the signal edges at the output of input flip-flop UDFF, the signals edgen and edgep at the outputs of the respective XOR gates U0N and U0P, the signals nout and pout at the outputs of the respective inverters U2N and U2P of the first and second inverter chains, the first digital output signal qn[0:31]=qn[0], qn[1], . . . qn[31] provided by the first bank of flip-flops UDN0 through UDN31, and the second digital output signal qp[0:31]=qp[0], qp[1], . . . qp[31] provided by the second bank of flip-flops UDP0 through UDP31. The signals of the FIG. 4 timing diagram are shown in volts (V) as a function of time in nanoseconds (ns).

In operation, a pulse is applied to the start signal input of the transistor mismatch sensor 110. On the next rising edge of clk, the pulse appears in the edges signal at the output of flip-flop UDFF. The XOR gates U0N and U0P transform the single-ended signal edges into the differential signals edgen and edgep.

It can be seen from the FIG. 4 timing diagram that the signals edgen and edgep at the outputs of the respective XOR gates U0N and U0P are complementary signals having substantially aligned transition times, including in this example a rising edge in the signal edgep that is aligned with a falling edge in the signal edgen and a falling edge in the signal edgep that is aligned with a rising edge in the signal edgen. These edges define respective positive and negative pulses in the signals edgep and edgen each having a width that corresponds generally in this example to the width of the pulse of the edges signal that is generated from the corresponding pulse in the start signal.

The signals edgen and edgep drive the respective initial inverters U1N and U1P of the respective first and second inverter chains. As described previously, the initial inverters U1N and U1P of the respective first and second inverter chains are heavily loaded so as to exaggerate transition timing differences between the transistors of the different conductivity types in the corresponding inverter chains.

Due to the heavy loading of the inverters U1N and U1P, the signals at nodes n₀ and p₀ have slow rise and fall times that can be used to measure NMOS and PMOS mismatch. For example, when the NMOS transistors are faster than the PMOS transistors, the falling edge rate will be faster than the rising edge rate. Similarly, when the NMOS transistors are slower than the PMOS transistors, the rising edge rate will be faster than the falling edge rate. This translates into a pronounced timing delay between the signals at nodes n₀ and p₀ at a point where these signals cross a voltage that is midway between the upper and lower supplies, in this case a 50% Vdd point, which is the point midway between Vdd and ground potential. By measuring the timing delay between n₀ and p₀ one can infer the amount of mismatch that exists between the NMOS and PMOS transistors.

The inverters U2N and U2P provide the respective output signals nout and pout in which normal rising and falling edge rates are restored but the timing delay previously established between n₀ and p₀ at the 50% Vdd point is preserved. The signal nout is used to provide clock signals for the banks of flip-flops in the 32-bit thermometer encoded register 302, while the signal pout is used to provide data signals for the banks of flip-flops. As noted above, the data signals are sent down the differential delay line comprising the differential delay elements UE0, UE1, . . . UE31.

In each of the banks of flip-flops, the corresponding thermometer encoded output measures how far down the differential delay line the data signal has propagated before it is captured by clocking of the flip-flops. More particularly, the qn[31:0] output of the first bank of flip-flops measures the timing delay between nout rising and pout falling at the 50% Vdd point, and the qp[31:0] output of the second bank of flip-flops measures the timing delay between nout falling and pout rising at the 50% Vdd point.

Accordingly, the timing delays between nout and pout in the present embodiment are measured by establishing race conditions between corresponding clock and data signals via the differential delay line. The timing delays are measured by the number of delay elements UE0, UE1, . . . UE31 that the data signal pulse has passed through before the corresponding clock pulse reaches the clock input of the flip-flops. As mentioned previously, the timing resolution of the circuit in this embodiment is one inverter delay.

The transistor mismatch sensor 110 may be tuned such that when the NMOS and PMOS transistors are matched, the value of both qn[31:0] and qp[31:0] will be close to a designated half value, such as 0x00007FFF+/−1 bit. Such circuit tuning may be accomplished, for example, by delaying the nout signal used to provide clock signals to the banks of flip-flops in a clock delay element, although such an element is omitted from the figure for simplicity and clarity of illustration.

Several different cases of relative NMOS and PMOS transistor mismatch that may arise in the transistor mismatch sensor 110 are illustrated in the timing diagrams of FIGS. 5A through 5D. At the top of each of these diagrams, the nout and pout signals are superimposed to illustrate differences in the timing of their respective falling and rising edges. Thus, in each diagram a falling edge is shown for nout superimposed on a corresponding rising edge for pout. Also shown in each diagram is the signal clkn applied to the clock inputs of the second bank of flip-flops UDP0 through UDP31. Each diagram also shows the superimposed data signals op₀, op₁, . . . op₃₁ of the second bank of flip-flops UDP0 through UDP31, and a corresponding hexadecimal value of the second digital output signal comprising bits qp[0], qp[1], . . . qp[31] at the respective outputs of flip-flops UDP0 through UDP31.

In the FIG. 5A diagram, both NMOS and PMOS transistors are slow, leading to an output value of 0x00007FFF.

In the FIG. 5B diagram, the NMOS transistors are slow and the PMOS transistors are fast, leading to an output value of 0x000003FF.

In the FIG. 5C diagram, both NMOS and PMOS transistors are fast, leading to an output value of 0x00003FFF.

In the FIG. 5D diagram, the NMOS transistors are fast and the PMOS transistors are slow, leading to an output value of 0x0007FFFF. Accordingly, in the FIG. 3 embodiment, high amounts of transistor mismatch skewed in one manner (e.g., slow NMOS, fast PMOS) lead to low qp[31:0] output values while high amounts of transistor mismatch skewed in the opposite direction (e.g., fast NMOS, slow PMOS) lead to high qp[31:0] output values. Intermediate qp[31:0] output values between the low and high output values generally correspond to cases of lower transistor mismatch (e.g., both NMOS and PMOS slow, or both NMOS and PMOS fast).

As indicated previously, the heavily loaded inverter chains in the transistor mismatch sensor 110 in the FIG. 3 embodiment exaggerate the timing differences between the NMOS and PMOS transistors. By measuring timing differences between the two inverter chains utilizing the thermometer encoded register 302, one can determine mismatch in speed, drive strength or other characteristics between the NMOS and PMOS transistors.

Again, when the PMOS and NMOS transistors are matched, the thermometer encoded register output value is approximately at half value. If the NMOS transistors are slower than the PMOS transistors, the thermometer encoded register output value will be less than half value. Conversely, if the NMOS transistors are faster than the PMOS transistors, then the thermometer encoded register will be greater than half value. As mentioned above, the half value in a given embodiment is tuned to a value of 0x00007FFF+/−1 bit, although other values can of course be used in other embodiments.

The transistor mismatch sensor 110 of FIG. 3 provides significant improvements relative to conventional arrangements. For example, it is an all-digital transistor mismatch sensor in which measurements are substantially independent of voltage and temperature. Also, due to the self-timed configuration of the sensor, the measurements are substantially independent of clock frequency. Moreover, the transistor mismatch sensor can be implemented so as to consume dynamic power only when making a measurement, and therefore without unduly increasing the power consumption of the corresponding integrated circuit. It should be noted, however, that the sensor consumes leakage power regardless of whether or not measurements are being made, and this leakage power will generally be dependent upon factors such as temperature and process variations.

It is to be appreciated that the particular testing system, tester and transistor mismatch sensor arrangements shown in FIGS. 1-3 are presented by way of illustrative example only, and numerous alternative arrangements of circuitry and other system elements may be used to implement transistor mismatch sensing functionality in the manner disclosed herein.

As indicated above, embodiments of the invention may be implemented in the form of integrated circuits. In a given such integrated circuit implementation, identical die are typically formed in a repeated pattern on a surface of a semiconductor wafer. Each die includes at least one transistor mismatch sensor as described herein, and may include other structures or circuits. The individual die are cut or diced from the wafer, then packaged as an integrated circuit. One skilled in the art would know how to dice wafers and package die to produce integrated circuits. Integrated circuits so manufactured are considered embodiments of this invention.

It should once again be emphasized that the embodiments of the invention as described herein are intended to be illustrative only. For example, other embodiments of the invention can be implemented using a wide variety of different types of logic gates and other circuitry, providing different configurations of mismatch amplification circuitry and associated registers. Also, different input and output signaling arrangements may be utilized. These and numerous other alternative embodiments within the scope of the following claims will be readily apparent to those skilled in the art.

What is claimed is:

1. An apparatus comprising:
first and second inverter chains; and
a register comprising a plurality of flip-flops having clock inputs driven by an output of the first inverter chain and data inputs driven by an output of the second inverter chain;
wherein data outputs of the flip-flops of the register are indicative of an amount of mismatch between transistors of different conductivity types in the first and second inverter chains.

2. The apparatus of claim 1 wherein the first and second inverter chains are part of mismatch amplification circuitry that further comprises an input circuit configured to generate complementary input signals for application to respective inputs of the first and second inverter chains.

3. The apparatus of claim 2 wherein the complementary input signals have substantially aligned transition times, and wherein said substantially aligned transition times are provided despite any mismatch between transistors of different conductivity types in the input circuit.

4. The apparatus of claim 2 wherein the input circuit comprises:
an input flip-flop having a data input driven by a start signal, a clock input driven by a clock signal, and a data output;
first and second logic gates each having an input coupled to the data output of the input flip-flop;
wherein outputs of the first and second logic gates are coupled to the respective inputs of the first and second inverter chains.

5. The apparatus of claim 4 wherein the first and second logic gates comprise respective first and second exclusive-or gates, with the first exclusive-or gate having a first input coupled to an upper supply voltage and a second input coupled to the data output of the input flip-flop, and the second exclusive-or gate having a first input coupled to the data output of the input flip-flop and a second input coupled to a lower supply voltage.

6. The apparatus of claim 1 wherein the inverter chains each comprise an initial inverter and at least one additional inverter arranged in series with the initial inverter and wherein an output of the initial inverter is heavily loaded so as to exaggerate transition timing differences between the transistors of the different conductivity types in the corresponding inverter chains.

7. The apparatus of claim 6 wherein the transition timing differences are reflected in a difference between a pulse width from a rising edge to a falling edge in one of the first and second inverter chains and a pulse width from a falling edge to a rising edge in the other of the first and second inverter chains

8. The apparatus of claim 6 wherein the output of the initial inverter in a given one of the first and second inverter chains is heavily loaded by coupling that output to inputs of respective additional inverters each having a drive strength that is substantially larger than a drive strength of the initial inverter.

9. The apparatus of claim 8 wherein the drive strength of a given one of the additional inverters is at least about 16 times the drive strength of the initial inverter.

10. The apparatus of claim 1 wherein the register comprises a thermometer encoded register providing at least one digital output signal having a first value indicative of an approximate match in at least one of speed and drive strength between the transistors of the first and second conductivity types.

11. The apparatus of claim 10 wherein the transistors of the first and second conductivity types comprise respective NMOS and PMOS transistors, and wherein the digital output signal having a value less than the first value indicates that the NMOS transistors are slower than the PMOS transistors and the digital output signal having a value greater than the first value indicates that the NMOS transistors are faster than the PMOS transistors.

12. The apparatus of claim 10 wherein the transistors of the first and second conductivity types comprise respective NMOS and PMOS transistors, and wherein the digital output signal having a value less than the first value indicates that the PMOS transistors are slower than the NMOS transistors and the digital output signal having a value greater than the first value indicates that the PMOS transistors are faster than the NMOS transistors.

13. The apparatus of claim 10 wherein the thermometer encoded register comprises:
a first input circuit driven by an output of the first inverter chain; and
a second input circuit driven by an output of the second inverter chain;
the plurality of flip-flops being arranged in first and second banks of flip-flops;
the first input circuit generating complementary clock signals for application to clock inputs of the flip-flops of the respective first and second banks of flip-flops;
the second input circuit generating complementary data signals for application to data inputs of the flip-flops of the respective first and second banks of flip-flops.

14. The apparatus of claim 13 wherein a given one of the first and second input circuits comprises first and second logic gates each having an input coupled to an output of the corresponding inverter chain.

15. The apparatus of claim 14 wherein the first and second logic gates comprise respective first and second exclusive-or gates, with the first exclusive-or gate having a first input coupled to an upper supply voltage and a second input coupled to the output of the corresponding inverter chain, and the second exclusive-or gate having a first input coupled to the output of the corresponding inverter chain and a second input coupled to a lower supply voltage.

16. The apparatus of claim 10 wherein the thermometer encoded register further comprises a differential delay line comprising a plurality of differential delay elements arranged in series with one another, with an initial one of the differential delay elements having first and second inputs coupled to respective outputs of the second input circuit and receiving the respective complementary data signals therefrom.

17. The apparatus of claim 16 wherein the differential delay elements other than a final one of the differential delay elements have first and second outputs that are coupled to respective data inputs of corresponding flip-flops in the first and second banks of flip-flops.

18. The apparatus of claim 13 wherein a race condition created between the clock signal and the corresponding data signal in at least a given one of the first and second banks of flip-flops controls a value of the digital output signal.

19. The apparatus of claim 1 wherein the apparatus is implemented in the form of an integrated circuit.

20. A method comprising:
driving clock inputs of flip-flops of a register with an output of a first inverter chain; and
driving data inputs of the flip-flops of the register with an output of a second inverter chain;
wherein data outputs of the flip-flops of the register are indicative of an amount of mismatch between transistors of different conductivity types in the first and second inverter chains.

21. The method of claim 20 wherein the register comprises a thermometer encoded register and the method further comprises providing a digital output signal having a first value indicative of an approximate match in at least one of speed and drive strength between the transistors of the first and second conductivity types, with values above and below the first value being indicative of respective first and second different types of relative mismatch in at least one of speed and drive strength between the transistors of the first and second conductivity types.

22. A computer program product comprising a computer-readable storage medium having computer program code embodied therein, wherein the computer program code when executed causes the method of claim 20 to be performed.

23. An apparatus comprising:
a tester comprising a processor coupled to a memory;
wherein the tester is configured to generate one or more control signals for controlling a transistor mismatch sensor of an integrated circuit, the transistor mismatch sensor comprising:
first and second inverter chains; and
a register comprising a plurality of flip-flops having clock inputs driven by the first inverter chain and data inputs driven by the second inverter chain;
wherein the tester is further configured to process data outputs of the flip-flops of the register, the data outputs of the flip-flops of the register being indicative of an amount of mismatch between transistors of different conductivity types in the first and second inverter chains.

24. The apparatus of claim 23 where the tester is at least partially implemented within the integrated circuit.
